(19) United States
(12) Patent Application Publication
(10) Pub. No.: US 2025/0254883 A1
(43) Pub. Date: Aug. 7, 2025

(54) THREE-DIMENSIONAL SEMICONDUCTOR MEMORY DEVICE AND ELECTRONIC SYSTEM INCLUDING THE SAME

(71) Applicant: Samsung Electronics Co., Ltd., Suwon-si (KR)

(72) Inventors: Ji-Sung KIM, Suwon-si (KR); Jaewoo PARK, Suwon-si (KR); Haeyeon JUN, Suwon-si (KR)

(21) Appl. No.: 18/892,828

(22) Filed: Sep. 23, 2024

(30) Foreign Application Priority Data
Feb. 6, 2024 (KR) 10-2024-0018387

(51) Int. Cl. H10B 51/20; H01L 25/065; H10B 43/10; H10B 43/27; H10B 51/10; H10B 80/00

(52) U.S. Cl. CPC H10B 51/20; H01L 25/0652; H10B 43/10; H10B 43/27; H10B 51/10; H10B 80/00; H01L 2225/06506

(57) ABSTRACT

A three-dimensional semiconductor memory device includes a substrate, a stacked structure including gate electrodes stacked on the substrate in a first direction perpendicular to a lower surface of the substrate, a semiconductor pattern penetrating the stacked structure and extending in the first direction, and a data storage pattern penetrating the stacked structure and extending in the first direction between the stacked structure and the semiconductor pattern, wherein the data storage pattern includes a charge storage layer between the gate electrodes and the semiconductor pattern, a ferroelectric layer between the charge storage layer and the semiconductor pattern, and an internal insulating layer between the charge storage layer and the ferroelectric layer, and the internal insulating layer includes at least one of a first material having a greater band gap than each of the charge storage layer and the ferroelectric layer, and a second material that is a high-k dielectric.

### CROSS-REFERENCE TO RELATED APPLICATION

This U.S. non-provisional patent application claims priority under 35 U.S.C. § 119 to Korean Patent Application No. 10-2024-0018387 filed on Feb. 6, 2024, in the Korean Intellectual Property Office, the entire contents of which are hereby incorporated by reference.

### BACKGROUND OF THE INVENTION

Aspects of the inventive concept relate to a three-dimensional semiconductor memory device and an electronic system including the same.

A demand may arise to have a semiconductor device capable of storing a large amount of data in an electronic system which may need data storage. Semiconductor devices have been highly integrated to meet high performance and low manufacturing cost, which are desired by customers. Integration of typical two-dimensional or planar semiconductor devices is primarily determined by the area occupied by a unit memory cell, such that it is greatly influenced by the level of technology for forming fine patterns. However, the expensive processing equipment needed to increase pattern fineness may set a practical limitation on increasing the integration of the two-dimensional or planar semiconductor devices. Therefore, there have been proposed three-dimensional semiconductor memory devices having three-dimensionally arranged memory cells.

### SUMMARY

Aspects of the inventive concept provide a three-dimensional semiconductor memory device with improved reliability and an electronic system including the same.

The problem to be solved by the inventive concept is not limited to the problems mentioned above, and other problems and/or solutions not mentioned will be clearly understood by those skilled in the art from the description below.

A three-dimensional semiconductor memory device according to some embodiments of the inventive concept may include a substrate, a stacked structure including gate electrodes stacked on the substrate in a first direction perpendicular to a lower surface of the substrate, a semiconductor pattern penetrating the stacked structure and extending in the first direction, and a data storage pattern penetrating the stacked structure and extending in the first direction, the data storage pattern being between the stacked structure and the semiconductor pattern, wherein the data storage pattern includes a charge storage layer between the gate electrodes and the semiconductor pattern, a ferroelectric layer between the charge storage layer and the semiconductor pattern, and an internal insulating layer between the charge storage layer and the ferroelectric layer, and the internal insulating layer includes at least one of a first material having a greater band gap than each of the charge storage layer and the ferroelectric layer, and a second material that is a high-k dielectric.

A three-dimensional semiconductor memory device according to some embodiments of the inventive concept may include a substrate, a stacked structure including gate electrodes stacked on the substrate in a first direction perpendicular to a lower surface of the substrate, a semiconductor pattern penetrating the stacked structure and extending in the first direction, and a data storage pattern penetrating the stacked structure and extending in the first direction, the data storage pattern being between the stacked structure and the semiconductor pattern, wherein the data storage pattern includes a charge storage layer between the gate electrodes and the semiconductor pattern, a ferroelectric layer between the charge storage layer and the semiconductor pattern, and an internal insulating layer between the charge storage layer and the ferroelectric layer, and the internal insulating layer includes at least one of a first material having a band gap of 5.5 [eV] or more and a second material that is a high-k dielectric.

An electronic system according to some embodiments of the inventive concept may include a three-dimensional semiconductor memory device and a controller electrically connected to the three-dimensional semiconductor memory device through an input/output pad and configured to control the three-dimensional semiconductor memory device, wherein the three-dimensional semiconductor memory device includes a substrate, a stacked structure including gate electrodes stacked on the substrate in a first direction perpendicular to a lower surface of the substrate, a semiconductor pattern penetrating the stacked structure and extending in the first direction, and a data storage pattern penetrating the stacked structure and extending in the first direction, the data storage pattern being between the stacked structure and the semiconductor pattern, the data storage pattern includes a charge storage layer between the gate electrodes and the semiconductor pattern, a ferroelectric layer between the charge storage layer and the semiconductor pattern, and an internal insulating layer between the charge storage layer and the ferroelectric layer, and the internal insulating layer includes at least one of a first material having a greater band gap than that of each of the charge storage layer and the ferroelectric layer, and a second material that is a high-k dielectric.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a diagram schematically showing an electronic system including a three-dimensional semiconductor memory device according to some embodiments of the inventive concept.

FIG. 2 is a perspective view schematically showing an electronic system including a three-dimensional semiconductor memory device according to some embodiments of the inventive concept.

FIG. 3 is a cross-sectional view illustrating a semiconductor package including a semiconductor device according to some embodiments of the inventive concept, and corresponds to a cross-section taken along line I-I′ of FIG. 2.

FIG. 4 is a cross-sectional view illustrating a semiconductor package including a semiconductor device according to some embodiments of the inventive concept, and corresponds to a cross-section taken along line II-II′ of FIG. 2.

FIG. 5 is a plan view showing a three-dimensional semiconductor memory device according to some embodiments of the inventive concept.

FIG. 6 is a cross-sectional view corresponding to line A-A′ in FIG. 5.

FIGS. 7A and 7B are enlarged views corresponding to ‘P1’ in FIG. 6, respectively.

FIGS. 8 and 9 are diagrams showing a method of manufacturing a three-dimensional semiconductor memory device according to some embodiments of the inventive concept, respectively.

### DETAILED DESCRIPTION

Hereinafter, a semiconductor device and a method of manufacturing the same according to embodiments of the inventive concept will be described in detail with reference to the drawings.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

As used herein, the terms “material continuity” and “materially in continuity” may refer to structures, patterns, and/or layers that are formed at the same time and of the same material, without a break in the continuity of the material of which they are formed. As one example, structures, patterns, and/or layers that are in “material continuity” or “materially in continuity” may be homogeneous monolithic structures.

The various patterns described herein, unless described otherwise, may each be a single continuous homogenous layer (formed of the same base material throughout). For example, these patterns may each be formed with a single corresponding process (e.g., in situ—in a chamber without vacuum break to the chamber).

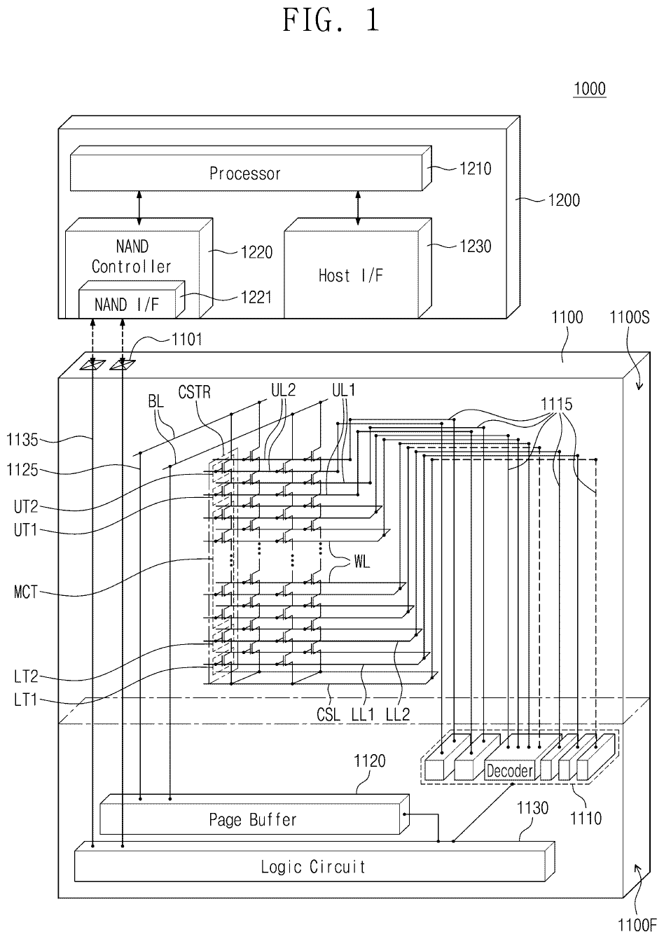

FIG. 1 is a diagram schematically showing an electronic system including a three-dimensional semiconductor memory device according to some embodiments of the inventive concept.

Referring to FIG. 1, an electronic system 1000 according to an embodiment of the present inventive concepts may include a three-dimensional semiconductor memory device 1100 and a controller 1200 electrically connected to the three-dimensional semiconductor memory device 1100. The electronic system 1000 may be a storage device that includes a single or a plurality of three-dimensional semiconductor memory devices 1100 or may be an electronic device that includes the storage device. For example, the electronic system 1000 may be a solid state drive (SSD) device, a universal serial bus (USB), a computing system, a medical apparatus, or a communication apparatus, each of which includes a single or a plurality of three-dimensional semiconductor memory devices 1100.

The three-dimensional semiconductor memory device 1100 may be a non-volatile memory device, such as a three-dimensional NAND Flash memory device which will be discussed below. The three-dimensional semiconductor memory device 1100 may include a first region 1100F and a second region 1100S on the first region 1100F. Different from that shown, the first region 1100F may be disposed on a side of (e.g., next to in any direction) the second region 1100S. The first region 1100F may be a peripheral circuit region that includes a decoder circuit 1110, a page buffer 1120, and a logic circuit 1130. The second region 1100S may be a memory cell region that includes bit lines BL, a common source line CSL, word lines WL, first lines LL1 and LL2, second lines UL1 and UL2, and memory cell strings CSTR between the bit line BL and the common source line CSL.

On the second region 1100S, each of the memory cell strings CSTR may include first transistors LT1 and LT2 adjacent to the common source line CSL, second transistors UT1 and UT2 adjacent to the bit line BL, and memory cell transistors MCT disposed between the first transistors LT1 and LT2 and the second transistors UT1 and UT2. The number of the first transistors LT1 and LT2 and of the second transistors UT1 and UT2 may be variously changed in accordance with embodiments.

For example, the second transistors UT1 and UT2 may include a string selection transistor, and the first transistors LT1 and LT2 may include a ground selection transistor. The first lines LL1 and LL2 may be gate electrodes of the first transistors LT1 and LT2, respectively. The word lines WL may be gate electrodes of the memory cell transistors MCT, and the second lines UL1 and UL2 may be gate electrodes of the second transistors UT1 and UT2, respectively.

For example, the first transistors LT1 and LT2 may include a first erase control transistor LT1 and aground selection transistor LT2 that are connected in series. For example, the second transistors UT1 and UT2 may include a string selection transistor UT1 and a second erase control transistor UT2 that are connected in series. For example, at least one of the first and second erase control transistors LT1 and UT2 may be employed to perform an erasure operation in which a gate induced drain leakage (GIDL) phenomenon is used to erase data stored in the memory cell transistors MCT, but the inventive concept is not limited thereto.

The common source line CSL, the first lines LL1 and LL2, the word lines WL, and the second lines UL1 and UL2 may be electrically connected to the decoder circuit 1110 through first connection lines 1115 that extend from the first region 1100F toward the second region 1100S. The bit lines BL may be electrically connected to the page buffer 1120 through second connection lines 1125 that extend from the first region 1100F toward the second region 1100S.

On the first region 1100F, the decoder circuit 1110 and the page buffer 1120 may perform a control operation to at least one selection memory cell transistor among the plurality of memory cell transistors MCT. The logic circuit 1130 may control the decoder circuit 1110 and the page buffer 1120. The three-dimensional semiconductor memory device 1100 may communicate with the controller 1200 through an input/output pad 1101 electrically connected to the logic circuit 1130. The input/output pad 1101 may be electrically connected to the logic circuit 1130 through an input/output connection line 1135 that extends from the first region 1100F toward the second region 1100S.

The controller 1200 may include a processor 1210, a NAND controller 1220, and a host interface 1230. According to some example embodiments, the electronic system 1000 may include a plurality of three-dimensional semiconductor memory devices 1100, and in this case, the controller 1200 may control the plurality of three-dimensional semiconductor memory devices 1100.

The processor 1210 may be configured to control overall operations of the electronic system 1000 including the controller 1200. The processor 1210 may operate based on predetermined firmware, and may control the NAND controller 1220 to access the three-dimensional semiconductor memory device 1100. The NAND controller 1220 may include a NAND interface 1221 that processes communication with the three-dimensional semiconductor memory device 1100. The NAND interface 1221 may be used to transfer therethrough a control command to control the three-dimensional semiconductor memory device 1100, data which is intended to be written on the memory cell transistors MCT of the three-dimensional semiconductor memory device 1100, and/or data which is intended to be read from the memory cell transistors MCT of the three-dimensional semiconductor memory device 1100. The host interface 1230 may provide the electronic system 1000 with communication with an external host. When a control command is received through the host interface 1230 from an external host, the three-dimensional semiconductor memory device 1100 may be controlled by the processor 1210 in response to the control command.

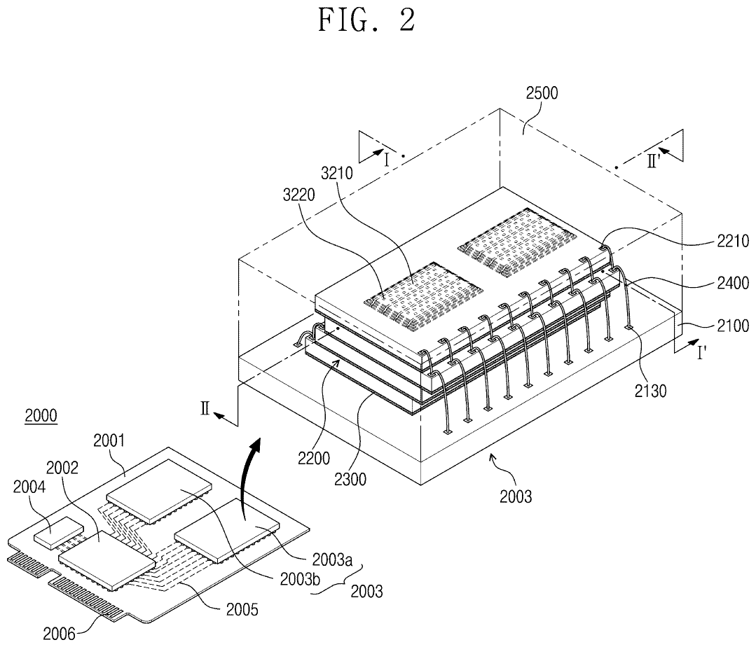

FIG. 2 is a perspective view schematically showing an electronic system including a three-dimensional semiconductor memory device according to some embodiments of the inventive concept.

Referring to FIG. 2, an electronic system 2000 according to an embodiment of the present inventive concepts may include a main board 2001, a controller 2002 mounted on the main board 2001, one or more semiconductor packages 2003, and a dynamic random access memory (DRAM) 2004. The semiconductor package 2003 and the DRAM 2004 may be connected to the controller 2002 through wiring patterns 2005 provided in the main board 2001.

The main board 2001 may include a connector 2006 including a plurality of pins which are provided to have connection with an external host. The number and arrangement of the plurality of pins on the connector 2006 may be changed based on a communication interface between the electronic system 2000 and the external host. The electronic system 2000 may communicate with the external host through one or more interfaces, for example, universal serial bus (USB), peripheral component interconnect express (PIC-Express), serial advanced technology attachment (SATA), and/or M-PHY for universal flash storage (UFS). For example, the electronic system 2000 may operate with power supplied through the connector 2006 from the external host. The electronic system 2000 may further include a power management integrated circuit (PMIC) that distributes the power supplied from the external host to the controller 2002 and the semiconductor package 2003.

The controller 2002 may write data to the semiconductor package 2003, may read data from the semiconductor package 2003, or may increase an operating speed of the electronic system 2000.

The DRAM 2004 may be a buffer memory that reduces a difference in speed between the external host and the semiconductor package 2003 that serves as a data storage space. The DRAM 2004 included in the electronic system 2000 may operate as a cache memory, and may provide a space for temporary data storage in a control operation of the semiconductor package 2003. When the DRAM 2004 is included in the electronic system 2000, the controller 2002 may include not only a NAND controller for control of the semiconductor package 2003, but a DRAM controller for control of the DRAM 2004.

The semiconductor package 2003 may include a first semiconductor package 2003a and a second semiconductor package 2003b that are spaced apart from each other. Each of the first and second semiconductor packages 2003a and 2003b may include a plurality of semiconductor chips 2200. Each of the first and second semiconductor packages 2003a and 2003b may include a package substrate 2100, semiconductor chips 2200 on the package substrate 2100, adhesive layers 2300 on bottom surfaces of the semiconductor chips 2200, connection structures 2400 that electrically connect the semiconductor chips 2200 to the package substrate 2100, and a molding layer 2500 that lies on the package substrate 2100 and covers or overlaps the semiconductor chips 2200 and the connection structures 2400.

The package substrate 2100 may be an integrated circuit board including package upper pads 2130. Each of the semiconductor chips 2200 may include input/output pads 2210. The input/output pads 2210 may correspond to the input/output pad 1101 of FIG. 1. Each of the semiconductor chips 2200 may include gate stack structures 3210 and vertical channel structures 3220. Each of the semiconductor chips 2200 may include a three-dimensional semiconductor memory device which will be discussed below.

The connection structures 2400 may be, for example, bonding wires that electrically connect the input/output pads 2210 to the package upper pads 2130. Therefore, on each of the first and second semiconductor packages 2003a and 2003b, the semiconductor chips 2200 may be electrically connected to each other in a wire bonding manner, and may be electrically connected to the package upper pads 2130 of the package substrate 2100. In some example embodiments, on each of the first and second semiconductor packages 2003a and 2003b, the semiconductor chips 2200 may be electrically connected to each other using through-silicon vias instead of the connection structures 2400 or the bonding wires.

Differently from that shown in FIG. 2, in some embodiments, the controller 2002 and the semiconductor chips 2200 may be included in a single package. The controller 2002 and the semiconductor chips 2200 may be mounted on a separate interposer substrate other than the main board 2001, and may be connected to each other through wiring lines provided in the interposer substrate.

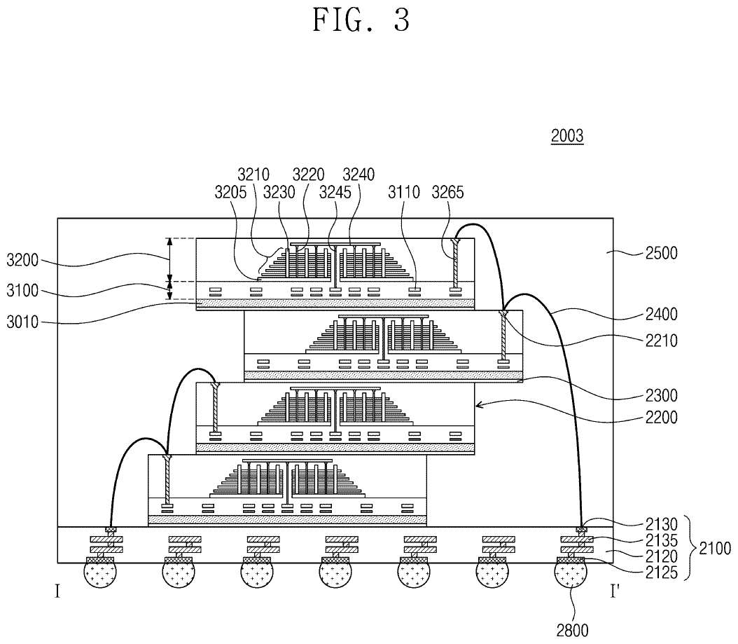

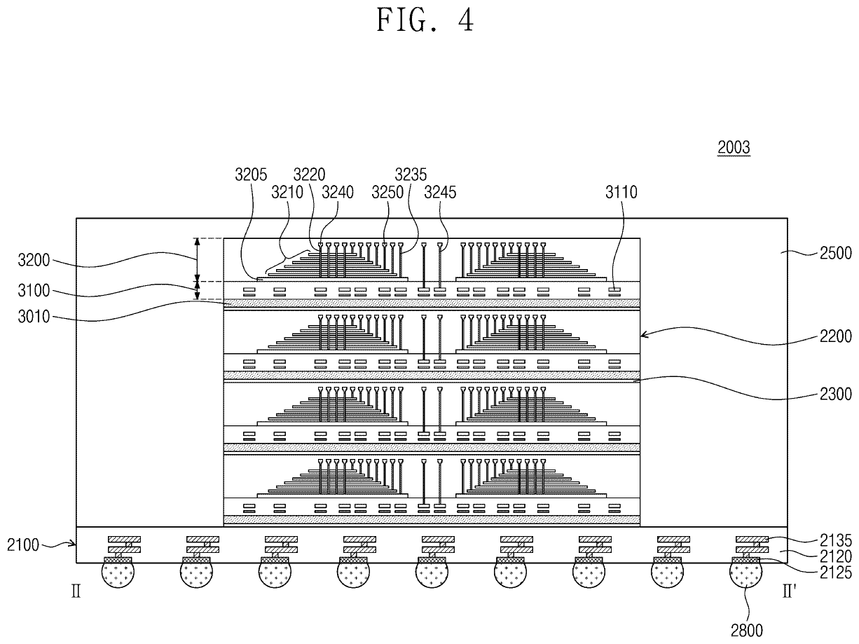

FIGS. 3 and 4 are cross-sectional views for explaining a semiconductor package including a semiconductor device according to some embodiments of the inventive concept, and correspond to cross-sections taken along lines I-I′ and II-II′ of FIG. 2, respectively.

Referring to FIGS. 3 and 4, a semiconductor package 2003 may include a package substrate 2100, a plurality of semiconductor chips on the package substrate 2100, and a molding layer 2500 that covers or overlaps the package substrate 2100 and the plurality of semiconductor chips.

The package substrate 2100 may include a package substrate body 2120, package upper pads 2130 on an upper surface of the package substrate body 2120, package lower pads 2125 disposed or exposed on a lower surface of the package substrate body 2120, and internal wirings 2135 that lie in the package substrate body 2120 and electrically connect the package upper pads 2130 to the package lower pads 2125. The package upper pads 2130 may be electrically connected to connection structures 2400. The package lower pads 2125 may be connected through conductive connectors 2800 to the wiring patterns 2005 in the main board 2001 of the electronic system 2000 depicted in FIG. 2.

Each of the semiconductor chips 2200 may include a semiconductor substrate 3010 and a first structure 3100 and a second structure 3200 that are sequentially stacked on the semiconductor substrate 3010. The first structure 3100 may include a peripheral circuit region including peripheral wirings 3110. The second structure 3200 includes a common source line 3205, a gate stacked structure 3210 on the common source line 3205, vertical channel structures 3220 and separation structure 3230 penetrating the gate stacked structure 3210, bit lines 3240 electrically connected to the vertical channel structures 3220, gate connection wirings 3235 and conductive lines 3250 electrically connected to the word lines WL (e.g., in FIG. 1) of the gate stacked structure 3210.

Each of the semiconductor chips 2200 may include a through wiring 3245 that is electrically connected to the peripheral wirings 3110 of the first structure 3100 and extends into the second structure 3200. The through wiring 3245 may penetrate the gate stacked structure 3210 and may be further disposed outside the gate stacked structure 3210. Each of the semiconductor chips 2200 may further include an input/output connection wiring 3265 that is electrically connected to the peripheral wirings 3110 of the first structure 3100 and extends into the second structure 3200, and input/output pads 2210 electrically connected to the input/output connection wiring 3265.

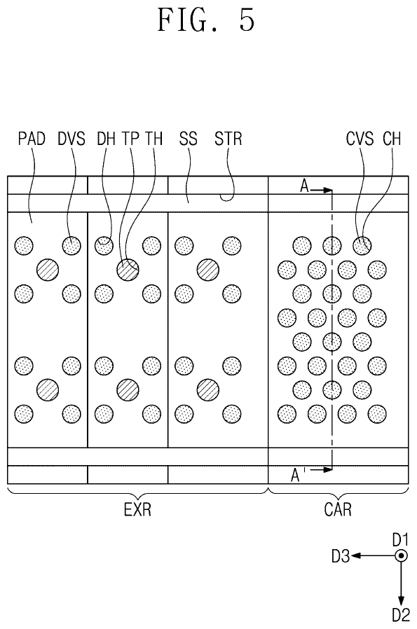

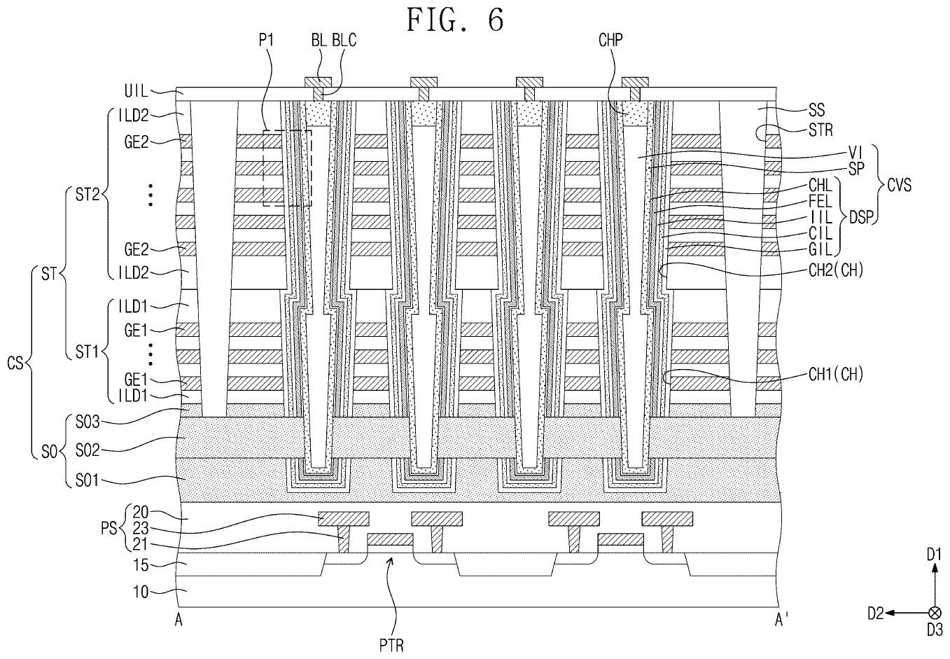

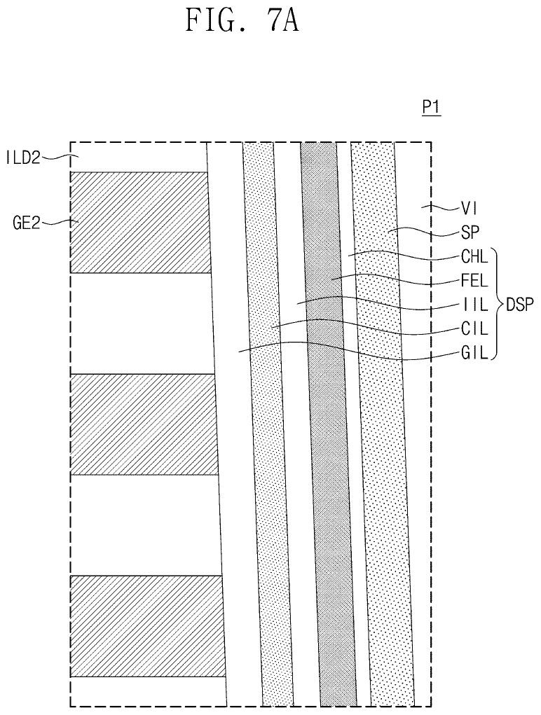

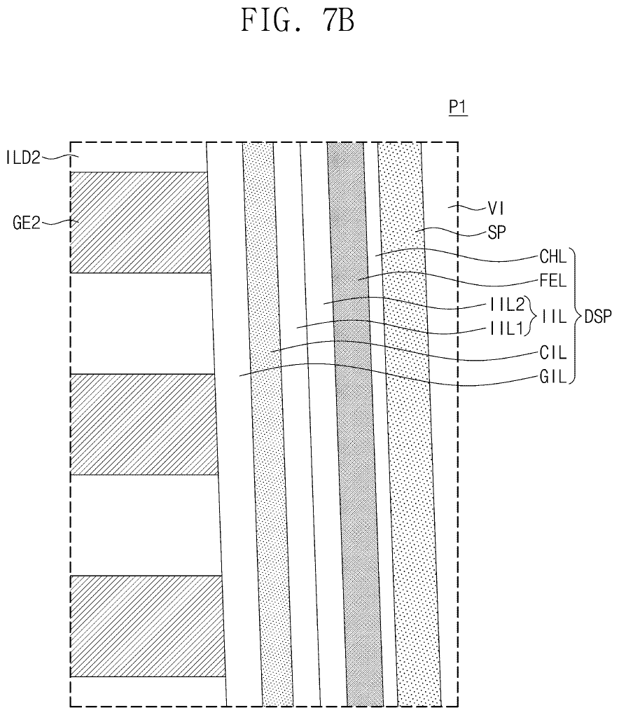

FIG. 5 is a plan view showing a three-dimensional semiconductor memory device according to some embodiments of the inventive concept. FIG. 6 is a cross-sectional view corresponding to line A-A′ in FIG. 5. FIGS. 7A and 7B are enlarged views corresponding to ‘P1’ in FIG. 6, respectively.

Referring to FIGS. 5 and 6, a three-dimensional semiconductor memory device according to some embodiments of the inventive concept may include a peripheral circuit structure PS and a cell array structure CS stacked on a substrate 10. The substrate 10 may correspond to the semiconductor substrate 3010 of FIGS. 3 and 4. The peripheral circuit structure PS may correspond to the first structure 3100 of FIGS. 3 and 4. The cell array structure CS may correspond to the second structure 3200 of FIGS. 3 and 4.

The substrate 10 may be, for example, a silicon substrate, a silicon-germanium substrate, a germanium substrate, or a single crystalline epitaxial layer grown on a monocrystalline silicon substrate. An upper surface of the substrate 10 may be perpendicular to a first direction D1. The upper surface of the substrate 10 may be parallel to each of second and third directions D2 and D3 that intersect each other. For example, the first to third directions D1, D2, and D3 may be orthogonal to each other. A device isolation layer 15 may be provided in the substrate 10. The device isolation layer 15 may define an active region of the substrate 10.

The peripheral circuit structure PS may include peripheral transistors PTR on the substrate 10, peripheral contact plugs 21, peripheral circuit wirings 23 electrically connected to peripheral transistors PTR through peripheral contact plugs 21, and a first insulating layer surrounding them.

The peripheral transistors PTR may be provided on the active region of the substrate 10. The peripheral circuit wirings 23 may correspond to the peripheral wirings 3110 of FIG. 3 or 4. The peripheral transistors PTR may constitute, for example, a decoder circuit 1110 (e.g., in FIG. 1), a page buffer 1120 (e.g., in FIG. 1), and a logic circuit 1130 (e.g., in FIG. 1). Each of the peripheral transistors PTR may be, for example, an NMOS transistor or a PMOS transistor. The peripheral contact plugs 21 and peripheral circuit wirings 23 may include a conductive material such as metal.

The first insulating layer 20 may include a plurality of insulating layers having a multilayer structure. As an example, the first insulating layer 20 may include at least one of silicon oxide, silicon nitride, silicon oxynitride, and a low dielectric material. In this specification, a low dielectric material is defined as a material having a lower dielectric constant than silicon oxide.

A cell array structure CS may be provided on the peripheral circuit structure PS. The cell array structure CS may include a source layer SO and a stacked structure ST sequentially stacked on the peripheral circuit structure PS, and a bit line BL on the stacked structure ST.

The source layer SO may include a first source layer SO1, a second source layer SO2, and a third source layer SO3 sequentially stacked on the peripheral circuit structure PS. The first to third source layers SO1, SO2, and SO3 may include a conductive material. As an example, the first to third source layers SO1, SO2, and SO3 may include polysilicon. For example, the second source layer SO2 may correspond to the common source line 3205 of FIGS. 3 and 4.

The stacked structure ST may be provided on the third source layer SO3. As an example, a second insulating layer (not shown) may be provided on the first source layer SO1. A second insulating layer may surround the stacked structure ST. The second insulating layer may include a plurality of insulating layers having a multilayer structure.

More than one of the stacked structure ST may be provided side by side. For example, when viewed in a plan view, the plurality of stacked structures ST may be spaced apart from each other in the second direction D2 and may each extend in the third direction D3. Hereinafter, for convenience of explanation, a single stacked structure ST will be described, but the following description may be equally applied to other stacked structures ST. The stacked structure ST may correspond to the gate stacked structure 3210 of FIGS. 3 and 4.

The stacked structure ST may include a first stacked structure ST1 and a second stacked structure ST2 sequentially stacked on the source layer SO. The first stacked structure ST1 may include first interlayer insulating layers ILD1 and first gate electrodes GE1 that are alternately stacked, and the second stacked structure ST2 may include second insulating layers ILD2 and second gate electrodes GE2 that are alternately stacked.

As an example, the first and second gate electrodes GE1 and GE2 may include at least one of a doped semiconductor (e.g., doped silicon, etc.), a metal (e.g., tungsten, copper, aluminum, etc.), a conductive metal nitride (e.g., titanium nitride, tantalum nitride, etc.) and a transition metal (e.g., titanium, tantalum, etc.). As an example, the first and second interlayer insulating layers ILD1 and ILD2 may include at least one of silicon oxide, silicon nitride, silicon oxynitride, and a low dielectric material.

Although not shown, when viewed in a cross-sectional perspective view, the stacked structure ST may have a stepped structure in the third direction D3 on a cell array extension region EXR. In other words, a thickness of the stacked structure ST in the cell array extension region EXR in the first direction D1 may decrease as a distance from the cell array region CAR increases. For example, a length of the first and second gate electrodes GE1 and GE2 in the third direction D3 may decrease as a distance from the substrate 10 increases. Each of the first and second gate electrodes GE1 and GE2 may include a pad portion PAD at one end in the third direction D3. The pad portion may be a region of each of the first and second gate electrodes GE1 and GE2 constituting the step portion of the stacked structure ST.

A through plug TP may penetrate the second insulating layer and extend in the first direction D1. The through plug TP may be electrically connected to the pad portion PAD and, for example, may be electrically connected to the corresponding gate electrodes GE1 and GE2 through the pad portion PAD. The through plug TP may include a conductive material such as metal.

One or more of the first gate electrodes GE1 may be ground selection lines GSL. The ground selection line GSL may control the ground selection transistor among the first transistors LT1 and LT2 described with reference to FIG. 1. As an example, the ground selection line GSL may be disposed below the stacked structure ST.

One or more of the second gate electrodes GE2 may be string selection lines SSL. The string selection line SSL may control a string selection transistor among the second transistors UT1 and UT2 described with reference to FIG. 1. As an example, the string selection line SSL may be disposed on an upper portion of the stacked structure ST.

Channel holes CH may penetrate the cell array structure CS in the cell array region CAR and the cell array extension region EXR. Each of the channel holes CH may penetrate at least one of the stacked structure ST and the second insulating layer in the first direction D1. As an example, each of the channel holes CH may include a first channel hole CH1 penetrating the first stacked structure ST1, and a second channel hole CH2 penetrating the second stacked structure ST2. For example, a width of each of the first and second channel holes CH1 and CH2 in the second direction D2 and/or the third direction D3 may increase in the first direction D1. For example, the width of each of the first and second channel holes CH1 and CH2 in the second direction D2 and/or the third direction D3 may increase with increasing distance from the substrate 10. The first and second channel holes CH1 and CH2 may be connected to each other. For example, the first and second channel holes CH1 and CH2 may extend vertically and may overlap each other when viewed in plan view. At a boundary where the first and second channel holes CH1 and CH2 are connected, a diameter of the second channel hole CH2 may be smaller than a diameter of the first channel hole CH1. The first and second channel holes CH1 and CH2 may have a step at the boundary where the first and second channel holes CH1 and CH2 are connected to each other, but are not limited thereto.

In the cell array region CAR, a cell vertical structure CVS may penetrate the stacked structure ST in the first direction D1 and conformally cover the channel hole CH. The cell vertical structures CVS may correspond to the vertical channel structures 3220 of FIGS. 3 and 4.

In the cell array extension region EXR, dummy vertical structures DVS may penetrate at least one of the stacked structure ST and the second insulating layer in the first direction D1 and fill the channel holes CH, respectively. Each of lower surfaces of the cell vertical structure CVS and the dummy vertical structure DVS may have a circular, oval, or bar shape, for example.

Each of the cell vertical structures CVS may include a data storage pattern DSP and a semiconductor pattern SP that sequentially cover inner sidewalls of the channel hole CH, conformally, and a buried insulating pattern VI that fills the inside of the channel hole CH and is surrounded by the semiconductor pattern SP.

The semiconductor pattern SP may be interposed between the data storage pattern DSP and the buried insulating pattern VI. The semiconductor pattern SP may penetrate the stacked structure ST and extend in the first direction D1 between the data storage pattern DSP and the buried insulating pattern VI. As an example, the semiconductor pattern SP may include a semiconductor material doped with an impurity, an intrinsic semiconductor material that is not doped with an impurity, or a polycrystalline semiconductor material.

The data storage pattern DSP may be interposed between the first gate electrode GE1 and the semiconductor pattern SP and between the second gate electrode GE2 and the semiconductor pattern SP. The data storage pattern DSP may penetrate the stacked structure ST and extend in the first direction D1 between the first and second gate electrodes GE1 and GE2 and the semiconductor pattern SP. One data storage pattern DSP may be adjacent to the first and second gate electrodes GE1 and GE2 in a horizontal direction.

The data storage pattern DSP may include a gate insulating layer GIL, a charge storage layer CIL, an internal insulating layer IIL, a ferroelectric layer FEL, and a channel insulating layer CHL that conformally cover the inner sidewalls of the channel hole CH, sequentially.

The gate insulating layer GIL may be interposed between the stacked structure ST and the charge storage layer CIL in the channel hole CH. Specifically, the gate insulating layer GIL may be interposed between the first and second gate electrodes GE1 and GE2 and the charge storage layer CIL. The gate insulating layer GIL may be in contact with the stacked structure ST. As an example, the stacked structure ST may further include an additional barrier layer (not shown) between the first and second gate electrodes GE1 and GE2 and the gate insulating layer GIL, and the gate insulating layer GIL may come into contact with the barrier layer. As an example, the gate insulating layer GIL may include at least one of SiO₂ and SiON.

The charge storage layer CIL may be interposed between the first and second gate electrodes GE1 and GE2 and the semiconductor pattern SP. As an example, the charge storage layer CIL may include at least one of SiN, SiON, Al₂O₃, and HfO₂, or at least one of SiN, SiON, Al₂O₃, and HfO₂, and SiO₂. The data storage pattern DSP may store and/or change data by using Fowler-Nordheim tunneling induced by a voltage difference between the semiconductor pattern SP and the first and second gate electrodes GE1 and GE2. In this case, as an example, the gate insulating layer GIL may be used as a tunneling insulating layer, and the charge storage layer CIL may serve to trap charges.

A ferroelectric layer FEL may be interposed between the charge storage layer CIL and the semiconductor pattern SP. The ferroelectric layer FEL may include a ferroelectric material that has polarization characteristics due to an electric field applied thereto. As an example, the ferroelectric layer FEL may be HfO₂, Si-doped HfO₂ (HfSiO₂), Al-doped HfO₂(HfAlO₂), Y-doped HfO₂ (HfYO₂), Sr-doped HfO₂ (HfSrO₂), Gd-doped HfO₂ (HfGdO₂), La-doped HfO₂ (HfLaO₂), HfSiON, HfZnO, HfZrO₂, ZrO₂, ZrSiO₂, HfZrSiO₂, ZrSiON, LaAlO, BaTiO3, AlScN, HfDyO₂, and HfScO₂. For example, a thickness of the ferroelectric layer FEL in the horizontal direction may be greater than a thickness of the charge storage layer CIL in the horizontal direction. For example, the ferroelectric layer FEL may not be interposed between the first and second gate electrodes GE1 and GE2, and the charge storage layer CIL. For example, the ferroelectric layer FEL may be disposed on the other side of the charge storage layer CIL from the first and second gate electrodes GE1 and GE2.

The ferroelectric layer FEL may have a spontaneous dipole (electric dipole), that is, spontaneous polarization, because charge distribution in each memory cell MCT is non-centrosymmetric. The ferroelectric layer FEL has a residual polarization due to a dipole even in absence of an external electric field. In addition, a direction of polarization may be switched by an external electric field.

In other words, the ferroelectric layer FEL may have a positive or negative polarization state, and the polarization state may be variously changed depending on the electric field applied to the ferroelectric layer FEL during a program operation. As the polarization state of the ferroelectric layer FEL changes, the data storage pattern DSP may store and/or change data. Additionally, the polarization state of the ferroelectric layer FEL may be maintained even when the power is turned off, and thus the three-dimensional semiconductor memory device may operate as a non-volatile memory device. For example, the polarization state of the ferroelectric layer FEL may be determined by a voltage difference between the gate electrodes GE1 and GE2. and the semiconductor pattern SP.

Accordingly, in the three-dimensional semiconductor memory device according to an embodiment of the inventive concept, both the polarization characteristics of the ferroelectric layer FEL and the charge trap characteristics of the charge storage layer CIL may be used, thereby increasing a memory window of the three-dimensional semiconductor memory device. In other words, in the three-dimensional semiconductor memory device according to an embodiment of the inventive concept, a wider threshold voltage distribution may be provided than would be provided using only one of the polarization characteristics of the ferroelectric layer FEL and the charge trap characteristic of the charge storage layer CIL.

An internal insulating layer IIL may be interposed between the charge storage layer CIL and the ferroelectric layer FEL. The internal insulating layer IIL may extend in the first direction D1 between the charge storage layer CIL and the ferroelectric layer FEL. An outer surface of the internal insulating layer IIL may be in contact with the charge storage layer CIL, and an inner surface of the internal insulating layer IIL may be in contact with the ferroelectric layer FEL.

The internal insulating layer IIL may include at least one of a first material having a band gap greater than a band gap of the material included in each of the charge storage layer CIL and the ferroelectric layer FEL, and a second material having high-k (e.g., a high-k dielectric). In this specification, a material having high-k (e.g., the high-k dielectric material) may be defined as a material with a higher dielectric constant than silicon oxide. For example, the band gap of the first material may be 5.5 [Ev] or more.

As an example, the first material may include at least one of SiON, BN, SiN, AlN, MgO, CaO, ZrSiO₄, HfSiO₄, Y₂O₃, and Al₂O₃. As an example, the second material may include at least one of SrTiO₃, BaTiO₃, TiO₂, HfO₂, ZrO₂, HfAlO, ZrAlO, and Al₂O₃.

According to aspects of the inventive concept, an internal insulating layer IIL including the first material may be interposed between the charge storage layer CIL and the ferroelectric layer FEL. Accordingly, charges trapped in the charge storage layer CIL may not leak to the ferroelectric layer FEL. As a result, the data of the data storage pattern DSP may not be unnecessarily changed, thereby improving reliability of the three-dimensional semiconductor memory device.

According to aspects of the inventive concept, the internal insulating layer IIL may be interposed between the charge storage layer CIL and the ferroelectric layer FEL, thereby increasing an equivalent oxide thickness (EOT) between the first gate electrode GE1 and the ferroelectric layer FEL and between the second gate electrode GE2 and the ferroelectric layer FEL. Accordingly, a memory window of the three-dimensional semiconductor memory device may be increased.

According to aspects of the inventive concept, an internal insulating layer IIL including the second material may be interposed between the charge storage layer CIL and the ferroelectric layer FEL. Accordingly, an increase in the operating voltage for storing data in the data storage pattern DSP may be minimized. In addition, the internal insulating layer IIL may be provided, the memory window of the three-dimensional semiconductor memory device may be maintained even when a thickness of the gate insulating layer GIL is smaller. Accordingly, an operating voltage may be reduced, and as a result, power consumption of the three-dimensional semiconductor memory device may be improved.

Referring to FIG. 7A, the internal insulating layer IIL may be composed of one layer (e.g., a single layer). As an example, the internal insulating layer IIL may include a first material or a second material. As another example (see, e.g., FIG. 7B), the internal insulating layer IIL may include each of the first material and the second material described above.

Referring to FIG. 7B, the internal insulating layer IIL may include a first internal insulating layer IIL1 and a second internal insulating layer IIL2 sequentially provided on the charge storage layer CIL. The first internal insulating layer IIL1 may be interposed between the charge storage layer CIL and the ferroelectric layer FEL. The second internal insulating layer IIL2 may be interposed between the first internal insulating layer IIL1 and the ferroelectric layer FEL. As an example, the first internal insulating layer IIL1 may include the first material, and the second internal insulating layer IIL2 may include the second material. As another example, the first internal insulating layer IIL1 may include the second material, and the second internal insulating layer IIL2 may include the first material. The first internal insulating layer IIL1 and the second internal insulating layer IIL2 may be in contact with each other.

Referring again to FIGS. 5 and 6, a channel insulating layer CHL may be interposed between the ferroelectric layer FEL and the semiconductor pattern SP in the channel hole CH. As an example, the channel insulating layer CHL may include at least one of SiO₂, SiON, AlON, Al₂O₃, C-doped SiO₂, SrTiO₃, BaTiO₃, TiO₂, HfO₂, ZrO₂, HfxAlyOz, and ZrxAlyOz. For example, although not shown in the drawing, the channel insulating layer CHL may not be interposed between the ferroelectric layer FEL and the semiconductor pattern SP.

A channel pad CHP may be provided on the buried insulating pattern VI. The channel pad CHP may fill the remainder of the channel hole CH and may be surrounded by the semiconductor pattern SP and the data storage pattern DSP. As an example, the channel pad CHP may include a semiconductor material doped with an impurity, an intrinsic semiconductor material not doped with an impurity, or a polycrystalline semiconductor material. As an example, the channel pad CHP and the semiconductor pattern SP may form an integrated shape without an interface. For example, the channel pad CHP and the semiconductor pattern SP may have material continuity with each other. For example, an upper surface of the channel pad CHP may be substantially coplanar with an upper surface of the stacked structure ST.

Each of separation trenches STR may extend in the first and third directions D1 and D3. The separation trenches STR may separate the stacked structures ST from each other in the second direction D2. Each of the separation trenches STR may extend from the cell array region CAR toward the cell array extension region EXR.

Separation patterns SS may fill the interior of the separation trenches STR. The separation patterns SS may correspond to the separation structures 3230 of FIG. 3. For example, upper surfaces of the separation patterns SS may be substantially coplanar with the upper surface of the stacked structure ST. As an example, the separation patterns SS may include at least one of silicon oxide, silicon nitride, silicon oxynitride, and a low dielectric material.

An upper insulating layer UIL may be provided on the stacked structure ST. As an example, the upper insulating layer UIL may include a plurality of insulating layers having a multilayer structure.

A bit line BL may be provided on the upper insulating layer UIL. The bit line BL may correspond to the bit line 3240 in FIGS. 3 and 4. A bit line contact BLC may penetrate the upper insulating layer UIL and may be in contact with an upper surface of the channel pad CHP. The bit line contact BLC may be interposed between the bit line BL and the channel pad CHP.

For example, the bit line BL and the bit line contact BLC may include a conductive material such as metal. Accordingly, the bit line BL may be electrically connected to the channel pad CHP through the bit line contact BLC. In addition, the bit line BL may be electrically connected to the semiconductor pattern SP through the channel pad CHP.

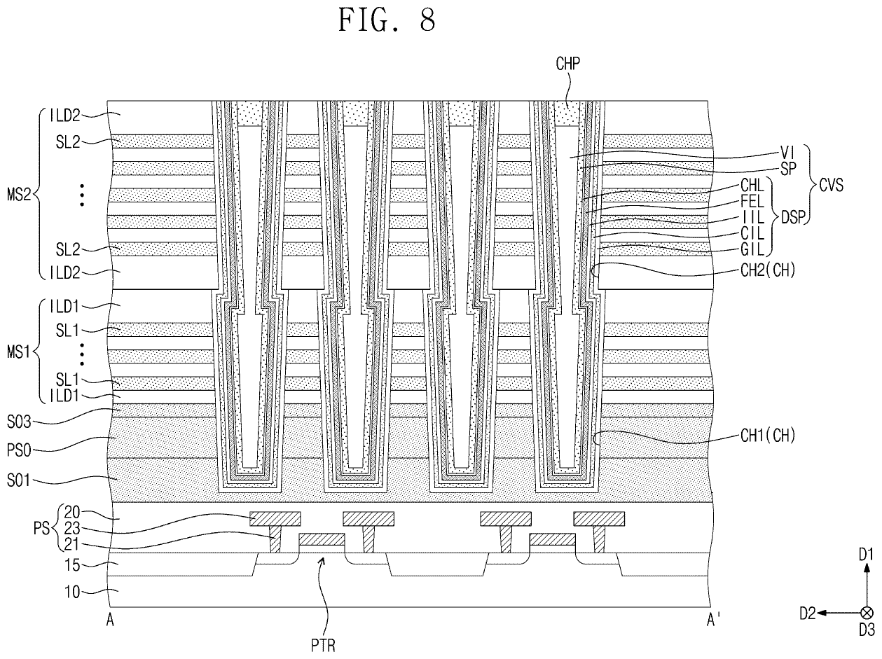

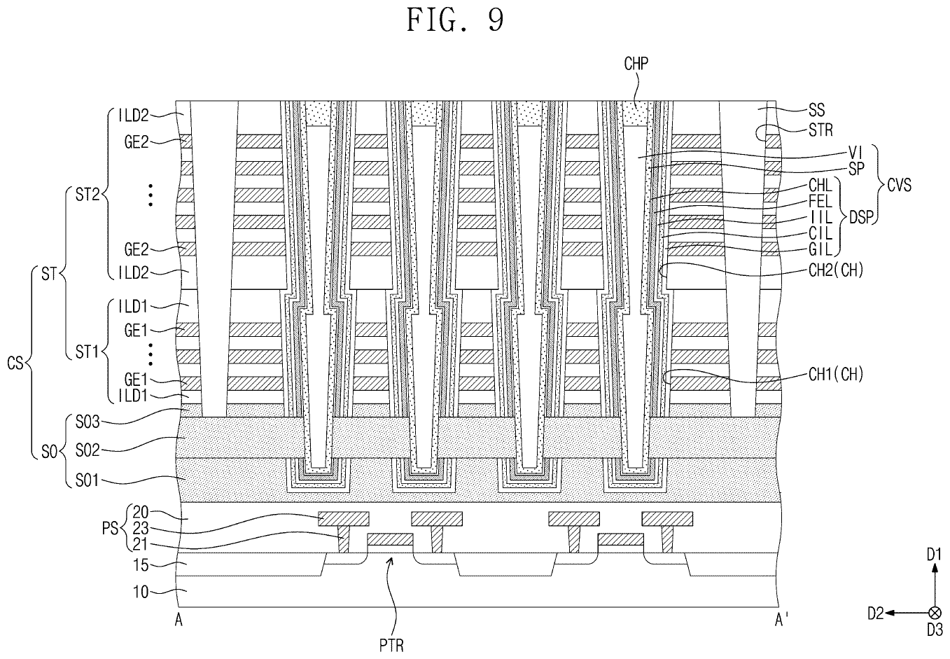

Hereinafter, a method of manufacturing a three-dimensional semiconductor memory device according to some embodiments of the inventive concept will be described with reference to FIGS. 8 and 9. To simplify the explanation, description of content that overlaps with the above-described content will be omitted, and the explanation will focus on the differences from the above-described content.

FIGS. 8 and 9 are diagrams for explaining a method of manufacturing a three-dimensional semiconductor memory device according to embodiments of the inventive concept. More specifically, FIGS. 8 and 9 are cross-sectional views corresponding to line A-A′ in FIG. 5, respectively.

Referring to FIGS. 5 and 8, a peripheral circuit structure PS may be formed on the substrate 10. Forming the peripheral circuit structure PS may include forming a device isolation layer 15 inside the substrate 10, and forming peripheral transistors PTR on an active region of the substrate 10 defined by the device isolation layer 15, and forming peripheral contact plugs 21 electrically connected to the peripheral transistors PTR, peripheral circuit wirings 23, and a first insulating layer 20 covering them.

A first source layer SO1, a preliminary source layer PSO, and a third source layer SO3 may be sequentially formed on the first insulating layer 20. As an example, the preliminary source layer may include an insulating material. A first mold structure MS1 may be formed on the third source layer SO3. The first mold structure MS1 may include first interlayer insulating layers ILD1 and first sacrificial layers SL1 that are alternately stacked. The first interlayer insulating layers ILD1 and the first sacrificial layers SL1 may include different insulating materials. As an example, the first interlayer insulating layers ILD1 may include silicon oxide, and the first sacrificial layers SL1 may include silicon nitride.

A first channel hole CH1 may be formed to penetrate the first interlayer insulating layers ILD1 and the first sacrificial layers SL1 in the first direction D1. In this case, components such as dummy holes DH (e.g., in FIG. 5) and through holes TH (e.g., in FIG. 5) may be formed together, but are not limited thereto.

A second mold structure MS2 may be formed on the first mold structure MS1. The second mold structure MS2 may include second interlayer insulating layers ILD2 and second sacrificial layers SL2 that are alternately stacked. The characteristics of the second interlayer insulating layers ILD2 and the second sacrificial layers SL2 may be the same/similar to those of the first interlayer insulating layers ILD1 and the first sacrificial layers SL1, respectively.

Thereafter, the second channel hole CH2 may be formed to penetrate the second interlayer insulating layers ILD2 and the second sacrificial layers SL2 in the first direction D1. In this case, components such as dummy holes DH (e.g., in FIG. 5) and through holes TH (e.g., in FIG. 5) may be formed together, but are not limited thereto. The first and second channel holes CH1 and CH2 may together constitute a channel hole CH.

A cell vertical structure CVS and a dummy vertical structure DVS (e.g., in FIG. 5) may be formed to fill the channel holes CH and dummy channel holes DH (e.g., in FIG. 5), respectively. Forming the cell vertical structure CVS may include sequentially and conformally forming a data storage pattern DSP and a semiconductor pattern SP in the channel hole CH, and forming a buried insulation pattern VI filling the remainder of the channel hole CH.

Forming the data storage pattern DSP may include sequentially forming a gate insulating layer GIL, a charge storage layer CIL, an internal insulating layer IIL, a ferroelectric layer FEL, and a channel insulating layer CHL in the channel hole CH.

Afterwards, a removal process may be performed on an upper portion of the buried insulating pattern VI. A channel pad CHP may be formed in the removed region of the buried insulating pattern VI.

Referring to FIGS. 5 and 9, a separation trench STR may be formed to penetrate the third source layer SO3 and the first and second mold structures MS1 and MS2. The second source layer SO2 may be formed to replace the preliminary source layer PSO exposed by the separation trench STR. The first to third source layers SO1, SO2, and SO3 may form the source layer SO.

Afterwards, an isotropic etching process using the separation trench STR as a path may be performed, and the first sacrificial layers SL1 and the second sacrificial layers SL2 may be removed. The first and second gate electrodes GE1 and GE2 may be formed in the places where the first sacrificial layers SL1 and the second sacrificial layers SL2 are removed, thereby forming a stacked structure ST. The separation pattern SS may be formed to fill the separation trench STR. Through plugs TP (e.g., in FIG. 5) may be formed to fill through holes TH (e.g., in FIG. 5).

Referring again to FIGS. 5 and 6, an upper insulating layer UIL may be formed on the stacked structure ST. A bit line contact BLC may be formed on an upper surface of the channel pad CHP to penetrate the upper insulating layer UIL. A bit line BL may be formed on the upper insulating layer UIL to be in contact with the bit line contact BLC.

According to aspects of the inventive concept, the internal insulating layer including the first material having the band gap greater than the band gap of the material included in each of the charge storage layer and the ferroelectric layer may be interposed between the charge storage layer and the ferroelectric layer. Accordingly, the charges trapped in the charge storage layer may not leak into the ferroelectric layer. As a result, the data in the data storage pattern may not be unnecessarily changed, thereby the reliability of the three-dimensional semiconductor memory device may be improved.

According to aspects of the inventive concept, the internal insulating layer is interposed between the charge storage layer and the ferroelectric layer, and thus the equivalent oxide thickness (EOT) between the first and second gate electrodes and the ferroelectric layer may be increased. Accordingly, the memory window of the three-dimensional semiconductor memory device may be increased.

According to aspects of the inventive concept, the internal insulating layer including a high-k second material may be interposed between the charge storage layer and the ferroelectric layer. Accordingly, the increase in the operating voltage for storing data in the data storage pattern may be minimized. In addition, as the internal insulating layer is provided, the memory window of the three-dimensional semiconductor memory device may be maintained even when the thickness of the gate insulating layer is formed smaller. Accordingly, the operating voltage may be reduced, thereby improving the power consumption of the three-dimensional semiconductor memory device.

While embodiments are described above, a person skilled in the art may understand that many modifications and variations are made without departing from the spirit and scope of the inventive concept. Accordingly, the example embodiments of the inventive concept should be considered in all respects as illustrative and not restrictive.

What is claimed is:

1. A three-dimensional semiconductor memory device comprising:
a substrate;
a stacked structure including gate electrodes stacked on the substrate in a first direction perpendicular to a lower surface of the substrate;
a semiconductor pattern penetrating the stacked structure and extending in the first direction; and
a data storage pattern penetrating the stacked structure and extending in the first direction, the data storage pattern being between the stacked structure and the semiconductor pattern,
wherein the data storage pattern includes a charge storage layer between the gate electrodes and the semiconductor pattern, a ferroelectric layer between the charge storage layer and the semiconductor pattern, and an internal insulating layer between the charge storage layer and the ferroelectric layer, and
wherein the internal insulating layer includes at least one of a first material having a greater band gap than each of the charge storage layer and the ferroelectric layer, and a second material that is a high-k dielectric.

2. The three-dimensional semiconductor memory device of claim 1, wherein the band gap of the first material is 5.5 [eV] or more.

3. The three-dimensional semiconductor memory device of claim 1, wherein the first material includes at least one of SiON, BN, SiN, AlN, MgO, CaO, ZrSiO₄, HfSiO₄, Y₂O₃, and Al₂O₃.

4. The three-dimensional semiconductor memory device of claim 1, wherein the second material includes at least one of SrTiO₃, BaTiO₃, TiO₂, HfO₂, ZrO₂, HfAlO, ZrAlO, and Al₂O₃.

5. The three-dimensional semiconductor memory device of claim 1, wherein the internal insulating layer includes the first material and the second material.

6. The three-dimensional semiconductor memory device of claim 1, wherein the internal insulating layer includes a first internal insulating layer between the charge storage layer and the ferroelectric layer, and a second internal insulating layer between the first internal insulating layer and the ferroelectric layer.

7. The three-dimensional semiconductor memory device of claim 6, wherein the first internal insulating layer includes the first material, and
wherein the second internal insulating layer includes the second material.

8. The three-dimensional semiconductor memory device of claim 6, wherein the first internal insulating layer includes the second material, and
wherein the second internal insulating layer includes the first material.

9. The three-dimensional semiconductor memory device of claim 1, wherein the ferroelectric layer is not between the gate electrodes and the charge storage layer.

10. The three-dimensional semiconductor memory device of claim 1, wherein, in a direction parallel to the lower surface of the substrate, a thickness of the ferroelectric layer is greater than a thickness of the charge storage layer.

11. A three-dimensional semiconductor memory device comprising:
a substrate;
a stacked structure including gate electrodes stacked on the substrate in a first direction perpendicular to a lower surface of the substrate;
a semiconductor pattern penetrating the stacked structure and extending in the first direction; and
a data storage pattern penetrating the stacked structure and extending in the first direction, the data storage pattern being between the stacked structure and the semiconductor pattern,
wherein the data storage pattern includes a charge storage layer between the gate electrodes and the semiconductor pattern, a ferroelectric layer between the charge storage layer and the semiconductor pattern, and an internal insulating layer between the charge storage layer and the ferroelectric layer, and
wherein the internal insulating layer includes at least one of a first material having a band gap of 5.5 [eV] or more and a second material that is a high-k dielectric.

12. The three-dimensional semiconductor memory device of claim 11, wherein the internal insulating layer includes the first material, and
wherein the band gap of the internal insulating layer is greater than a band gap of each of the charge storage layer and the ferroelectric layer.

13. The three-dimensional semiconductor memory device of claim 11, wherein the first material includes at least one of SiON, BN, SiN, AlN, MgO, CaO, ZrSiO₄, HfSiO₄, Y₂O₃, and Al₂O₃.

14. The three-dimensional semiconductor memory device of claim 11, wherein the second material includes at least one of SrTiO₃, BaTiO₃, TiO₂, HfO₂, ZrO₂, HfAlO, ZrAlO, and Al₂O₃.

15. The three-dimensional semiconductor memory device of claim 11, wherein the internal insulating layer includes a first internal insulating layer between the charge storage layer and the ferroelectric layer, and a second internal insulating layer between the first internal insulating layer and the ferroelectric layer.

16. The three-dimensional semiconductor memory device of claim 15, wherein the first internal insulating layer includes the first material, and
wherein the second internal insulating layer includes the second material.

17. The three-dimensional semiconductor memory device of claim 15, wherein the first internal insulating layer includes the second material, and
wherein the second internal insulating layer includes the first material.

18. The three-dimensional semiconductor memory device of claim 11, wherein the ferroelectric layer is not between the gate electrodes and the charge storage layer.

19. An electronic system comprising:
a three-dimensional semiconductor memory device; and
a controller electrically connected to the three-dimensional semiconductor memory device through an input/output pad and configured to control the three-dimensional semiconductor memory device,
wherein the three-dimensional semiconductor memory device includes:
a substrate;
a stacked structure including gate electrodes stacked on the substrate in a first direction perpendicular to a lower surface of the substrate;
a semiconductor pattern penetrating the stacked structure and extending in the first direction; and
a data storage pattern penetrating the stacked structure and extending in the first direction, the data storage pattern being between the stacked structure and the semiconductor pattern,
wherein the data storage pattern includes a charge storage layer between the gate electrodes and the semiconductor pattern, a ferroelectric layer between the charge storage layer and the semiconductor pattern, and an internal insulating layer between the charge storage layer and the ferroelectric layer, and
wherein the internal insulating layer includes at least one of a first material having a greater band gap than that of each of the charge storage layer and the ferroelectric layer, and a second material that is a high-k dielectric.

20. The electronic system of claim 19, wherein the first material includes at least one of SiO₂, SiON, BN, SiN, AlN, MgO, CaO, ZrSiO₄, HfSiO₄, Y₂O₃, and Al₂O₃.
